(19) United States
(12) Patent Application Publication
(10) Pub. No.: US 2026/0190922 A1
(43) Pub. Date: Jul. 2, 2026

(54) SUBSTRATE TREATING APPARATUS

(71) Applicants: SEMES CO., LTD., Cheonan-si (KR); Samsung Electronics Co., Ltd., Suwon-si (KR)

(72) Inventors: Jin Ah HAN, Cheonan-si (KR); Yong Hoon HONG, Seoul (KR); Hyun Woo TAK, Cheonan-si (KR); Hyeon Suk PARK, Cheonan-si (KR); Jong Kook PARK, Suwon-si (KR); Won Taek LEE, Suwon-si (KR); Dae Hyuk CHUNG, Suwon-si (KR); Jin Hyung PARK, Suwon-si (KR); Kyoung Suk KIM, Suwon-si (KR)

(73) Assignees: SEMES CO., LTD., Cheonan-si (KR); Samsung Electronics Co., Ltd., Suwon-si (KR)

(21) Appl. No.: 19/265,196

(22) Filed: Jul. 10, 2025

(30) Foreign Application Priority Data
Jan. 2, 2025 (KR) 10-2025-0000255

(51) Int. Cl. H01L 21/67

(52) U.S. Cl. CPC H10P 72/0604; H10P 72/0422

(57) ABSTRACT

A substrate treating apparatus is provided. The substrate treating apparatus comprises a substrate treating assembly including a substrate supporting unit configured to support a substrate treated with a treatment liquid and a bowl unit surrounding the substrate supporting unit; a tank unit including a plurality of tanks, the plurality of tanks including first and second tanks that are configured to receive the treatment liquid supplied to the substrate treating assembly and are arranged in series in a downstream direction, wherein the second tank is configured to supply the treatment liquid to the substrate; a liquid level detection unit configured to detect a liquid level of the tank unit; and a control unit configured to regulate a flow rate of the treatment liquid discharged from the tank unit based on the liquid level detected by the liquid level detection unit.

### CROSS-REFERENCE TO RELATED APPLICATION

This application claims priority from Korean Patent Application No. 10-2025-0000255 filed on Jan. 2, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate treating apparatus.

### 2. Description of the Related Art

A semiconductor manufacturing process, which is a process for fabricating a semiconductor product capable of processing electrical signals, may include a treating process (front-end process) in which patterns are formed on a wafer through treatments such as oxidation, exposure, etching, ion implantation, and deposition, and a packaging process (back-end process) in which a semiconductor package in the form of a finished product is manufactured through treatments such as dicing, die bonding, wiring, molding, marking, and testing on the patterned wafer.

During a semiconductor process, in particular, a cleaning process for removing thin films, foreign substances, and particles from a substrate may be performed by placing the substrate on a spin head with its patterned surface facing upward or downward, supplying a treatment liquid to the substrate while rotating the spin head, and subsequently drying the substrate.

For example, to remove a film containing titanium (Ti), such as a titanium nitride thin film, from a substrate, a mixture of a fluid containing an oxidizing agent such as hydrogen peroxide and water may be used as a treatment liquid. In this case, the concentration of hydrogen peroxide or Ti in the treatment liquid may influence the etching rate of the titanium nitride film.

The treatment liquid stored in a tank may be supplied to the substrate for processing, and the used treatment liquid may be recovered into the tank for reuse. During the reuse of the treatment liquid, the recovered treatment liquid may contain foreign substances detached from the substrate, such as Ti.

As the foreign substance Ti gradually increases, the concentration of hydrogen peroxide in the treatment liquid within the tank may gradually decrease over time because Ti may decompose hydrogen peroxide. Thus, if the treatment liquid is reused, the concentration of Ti increases while the concentration of hydrogen peroxide decreases, which may significantly reduce the etching rate during the etching of the substrate.

### SUMMARY

An objective of the present disclosure is to provide a substrate treating apparatus that enables efficient reuse of a treatment liquid, facilitates concentration management of the treatment liquid, and allows for frequent replenishment of the treatment liquid.

The objectives of the present disclosure are not limited to those mentioned above, and other objectives not explicitly stated will be clearly understood by those skilled in the art based on the following description.

According to an aspect of the present disclosure, a substrate treating apparatus includes: a substrate treating assembly including a substrate supporting unit configured to support a substrate treated with a treatment liquid and a bowl unit surrounding the substrate supporting unit; a tank unit including a plurality of tanks, the plurality of tanks including first and second tanks that are configured to receive the treatment liquid supplied to the substrate treating assembly and are arranged in series in a downstream direction, wherein the second tank is configured to supply the treatment liquid to the substrate; a liquid level detection unit configured to detect a liquid level of the tank unit; and a control unit configured to regulate a flow rate of the treatment liquid discharged from the tank unit based on the liquid level detected by the liquid level detection unit.

According to another aspect of the present disclosure, a substrate treating assembly including a substrate supporting unit configured to support a substrate and a bowl unit surrounding the substrate supporting unit; a first tank configured to receive a first fluid, store a second fluid mixed with the first fluid, and discharge the second fluid to the outside, the first tank including a first discharge line provided with a first concentration meter configured to measure a concentration of the second fluid; a supply line connecting the substrate treating assembly and the first tank; a second tank provided downstream of the first tank in the supply line and configured to supply the second fluid to the substrate treating assembly, and discharge the second fluid to the outside, the second tank including a second discharge line provided with a second concentration meter configured to measure a concentration of the second fluid; a third tank provided between the first and second tanks in the supply line, the third tank including a third discharge line configured to discharge the second fluid to the outside; branch lines branching from the supply line and respectively connected to the first, second, and third tanks; a recovery line through which a third fluid, which is the second fluid mixed with titanium after treating the substrate in the substrate treating assembly, flows, the recovery line connecting the substrate treating assembly and the first tank; a drain tank including a drain line that either branches from the recovery line or is connected near the recovery line to the substrate treating assembly, the drain tank being configured to store the third fluid; a third concentration meter provided in the drain line and configured to measure a concentration of the third fluid; a fourth concentration meter provided in the third discharge line and configured to measure a concentration of the second fluid discharged from the third tank; a heater provided upstream of a branch point of the branch lines in the supply line; and a control unit configured to receive concentration values measured by the first, second, and third concentration meters and to control flow rates of the first and second fluids, wherein at least one of the first, second, or third concentration meters is configured to detect a concentration of titanium contained in the second or third fluid, or a change in the concentration, and the control unit is further configured to: open the first, second, and third discharge lines when at least one of the first, second, third, or fourth concentration meters detects that the concentration of titanium in the second or third fluid is equal to or greater than 25 ppm; open the recovery line to recover the third fluid into the first tank when the concentration of titanium detected by the third concentration meter is less than 5 ppm; and open the drain line to discharge the third fluid into the drain tank when the concentration of titanium detected by the third concentration meter is equal to or greater than 5 ppm.

The substrate treating apparatus according to the present disclosure allows for easy monitoring of changes in the concentration trend of a treatment liquid and enables precise and convenient management of the concentration/flow rate of the treatment liquid, thereby facilitating the efficient reuse of the treatment liquid.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a diagram illustrating a substrate treating system according to some embodiments of the present disclosure;

FIG. 2 is a diagram illustrating a substrate treating apparatus according to a first embodiment of the present disclosure;

FIG. 3 is a diagram illustrating a substrate treating apparatus according to a second embodiment of the present disclosure;

FIG. 4 is a diagram for explaining the supply flow of a treatment liquid in the substrate treating apparatus according to the second embodiment of the present disclosure;

FIG. 5 is a diagram for explaining the circulation of the treatment liquid in the substrate treating apparatus according to the second embodiment of the present disclosure;

FIG. 6 is a diagram for explaining the foreign substance concentration in the substrate treating apparatus according to the second embodiment of the present disclosure;

FIG. 7 is a diagram illustrating process chambers in which substrate treating apparatuses according to a third embodiment of the present disclosure are provided;

FIG. 8 is a diagram illustrating the initial state of a tank unit for the substrate treating apparatuses according to the third embodiment of the present disclosure;

FIG. 9 is a diagram illustrating a state in which a second tank for the substrate treating apparatuses according to the third embodiment of the present disclosure is at or above a fourth level;

FIG. 10 is a diagram illustrating a state in which the second tank for the substrate treating apparatuses according to the third embodiment of the present disclosure is at or below the fourth level;

FIG. 11 is a diagram illustrating a state in which a third tank for the substrate treating apparatuses according to the third embodiment of the present disclosure is at or below the fourth level; and

FIG. 12 is a diagram illustrating an abnormal condition in the treatment liquid supplied to the third tank for the substrate treating apparatuses according to the third embodiment of the present disclosure.

### DETAILED DESCRIPTION

The following detailed description provides preferred embodiments of the present disclosure with reference to the accompanying drawings. The advantages and features of the present disclosure, as well as the methods of achieving them, will become apparent by referring to the detailed embodiments described below in conjunction with the drawings. However, the present disclosure is not limited to the embodiments disclosed herein and can be implemented in various forms. The provided embodiments are intended to fully disclose the invention and to convey the complete scope of the invention to those skilled in the art. The invention is defined only by the scope of the claims. Throughout the specification, like reference numerals refer to like elements.

The terminology used in this specification is intended to describe embodiments and is not intended to limit the invention. In this specification, the singular includes the plural unless otherwise specifically stated. The terms “comprises” and/or “comprising,” as used herein, do not exclude the presence or addition of one or more other elements, steps, operations, and/or features.

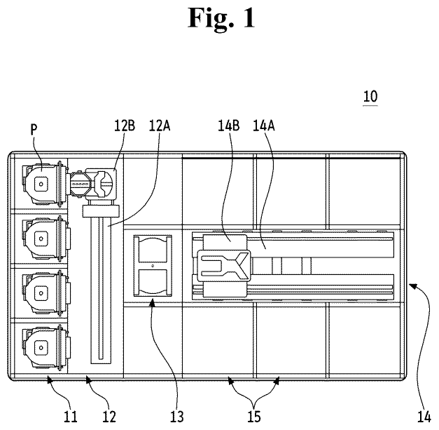

FIG. 1 is a diagram illustrating a substrate treating system according to some embodiments of the present disclosure.

Referring to FIG. 1, a substrate treating system 10 may include an index module (11 and 12) and process treating module (13, 14, and 15).

The index module (11 and 12) may be arranged in front of the process treating module (13, 14, and 15). The index module (11 and 12) may include load ports 11 and a first transfer frame 12.

The load ports 11 may be configured to receive carriers P in which substrates are housed. A plurality of load ports 11 may be provided in front of the first transfer frame 12. The load ports 11 may be arranged in a row parallel to the movement direction of the first transfer frame 12.

The number of load ports 11 may vary depending on the processing efficiency and footprint of the process treating module (13, 14, and 15).

The carriers P may each house multiple substrates. The carriers P may include slots (not illustrated) for supporting the edges of substrates. A plurality of slots may be provided in each of the carriers P. Substrates may be stacked inside each of the carriers P to be spaced apart in a vertical direction. The carriers P may, for example, be implemented as front opening unified pods (FOUPs).

The first transfer frame 12 may transfer substrates between the carriers P, which are placed on the load ports 11, and a buffer unit 13. The first transfer frame 12 may include an index rail 12A and an index robot 12B.

The index rail 12A may provide a path for the index robot 12B to move. The index rail 12A may be arranged parallel to the direction in which the carriers P are arranged.

The index robot 12B may directly transfer substrates. The index robot 12B may be installed on the index rail 12A and may move linearly along the direction in which the carriers P are arranged.

The process treating module (13, 14, and 15) may include the buffer unit 13, a second transfer frame 14, and process chambers 15.

The buffer unit 13 may provide a space where substrates temporarily remain before being transferred between the first and second transfer frames 12 and 14. For this purpose, the buffer unit 13 may be arranged between the first and second transfer frames 12 and 14.

The buffer unit 13 may include slots (not illustrated) where substrates are placed. A plurality of slots may be provided inside the buffer unit 13 to be spaced apart in the vertical direction. The surfaces of the buffer unit 13 that face the first and second transfer frames 12 and 14 may both be open.

The second transfer frame 14 may transfer substrates between the buffer unit 13 and the process chambers 15. The second transfer frame 14 may include a guide rail 14A and a substrate transfer unit 14B. If the process chambers 15 perform different processes or treatments, the second transfer frame 14 may transfer substrates between the process chambers 15 performing different processes.

The second transfer frame 14 may be arranged parallel to a direction perpendicular to the first transfer frame 12. A plurality of process chambers 15 (e.g., etching chambers and/or cleaning chambers) may be arranged on both sides of the second transfer frame 14 along the longitudinal direction of the second transfer frame 14.

The process chambers 15 may be arranged to be stacked in the vertical direction. The number of process chambers 15 may vary. The process chambers 15 may be provided only on one side of the second transfer frame 14 or may be provided in a single layer on one or both sides of the second transfer frame 14.

The process chambers 15 may receive treatment liquids for performing processes such as etching and/or cleaning. Each of the process chambers 15 may include a substrate treating assembly 101, and the substrate treating assembly 101 may include a substrate supporting unit 101C for supporting a substrate and a bowl unit 101B surrounding the substrate supporting unit 101C. For example, the substrate supporting unit 101C may be implemented as a chuck for holding a substrate, and the bowl unit 101B may include one or more cups. The specific details of these components will be omitted as they are part of known technology.

Substrate treating apparatuses 100 provided in the process chambers 15 will hereinafter be described.

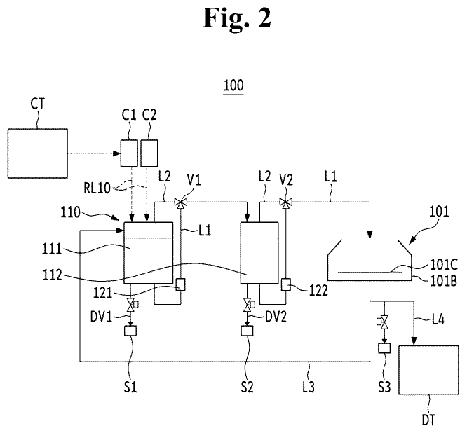

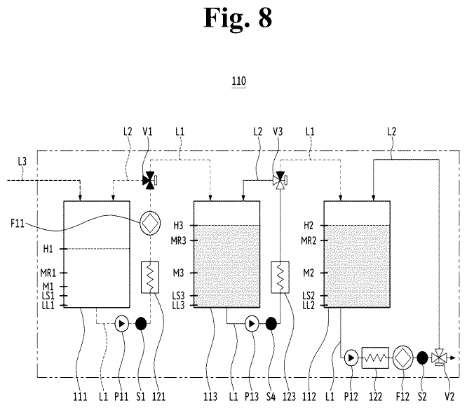

Before proceeding with the description, it is to be noted that embodiments mentioned herein and known technologies may be combined or configured to create other embodiments. For example, a liquid level detection unit (e.g., a first concentration meter S1) as mentioned in the embodiment disclosed in FIG. 8 may also be provided in a first embodiment disclosed in FIG. 2.

FIG. 2 is a diagram illustrating a substrate treating apparatus according to a first embodiment of the present disclosure.

Referring to FIG. 2, a substrate treating apparatus 10 according to some embodiments of the present disclosure may include a tank unit 110, a concentration measurement unit (e.g., a first concentration meter S1, a second concentration meter S2, and a third concentration meter S3), a recovery line L3, a drain line L4, and a control unit CT.

A first fluid, a second fluid, and a third fluid to be mentioned below may differ in concentrations of hydrogen peroxide and/or Ti, but may all refer to a treatment liquid used for substrate processing (e.g., an etching liquid containing an oxidizing agent or a replenishing liquid newly introduced into a first tank 111). In other words, the first, second, and third fluids may be classified based on their location and/or storage position within the substrate treating system 10, for ease of explanation and understanding. The first, second, and third fluids may all correspond to a treatment liquid for substrate treatment, differing in the concentration of foreign substances/Ti.

Additionally, a replenishing liquid to be mentioned in some embodiments refers to a treatment liquid newly supplied through a replenishing liquid line R10. For convenience of explanation, the replenishing liquid is distinguished from the treatment liquid, but may be the same as the treatment liquid initially stored in a second tank 112 and/or a third tank 113 in some embodiments. That is, the replenishing liquid may be a new treatment liquid that has not yet been used for substrate treatment and may have the same composition, material, and/or foreign substance content as the initially stored treatment liquid.

Furthermore, a third fluid discharged from a substrate treating assembly 101 may contain foreign substances detached from a titanium film formed on a substrate W, that is, titanium (Ti). Accordingly, a plurality of concentration meters (e.g., a first concentration meter S1, a second concentration meter S2, and a third concentration meter S3) to be described below may be concentration meters for measuring Ti concentration.

Moreover, concentration values (or measured values) to be described below refer to Ti concentration values, but the present disclosure is not limited thereto. Since concentration measurement is for the management of the treatment liquid, the concentration values may represent other foreign substances and/or hydrogen peroxide concentrations, and such variations do not conflict with the present disclosure.

Additionally, measuring the concentration of the treatment liquid using a plurality of concentration meters for a plurality of tanks (e.g., the first and second tanks 111 and 112) may refer to measuring the concentration of the treatment liquid inside each of the plurality of tanks and/or the treatment liquid discharged from each of the tanks.

In the first embodiment, the treatment liquid passing through the tank unit 110, which may include a plurality of tanks, may be supplied to a process chamber 15, and the concentration of the treatment liquid may be measured in real time at multiple locations.

The first tank 111 of the tank unit 110 may receive the first fluid and may store the second fluid mixed with the first fluid. The first fluid may include a first replenishing liquid C1 and/or a second replenishing liquid C2. The first replenishing liquid C1 may be, for example, an etching liquid containing an oxidizing agent such as hydrogen peroxide. The second replenishing liquid C2 may be water or an etch booster. The first and second replenishing liquids C1 and C2 are merely exemplary, and the present disclosure is not limited thereto. That is, only the first replenishing liquid C1 or only the second replenishing liquid C2 may be supplied to the first tank 111, among other possible variations.

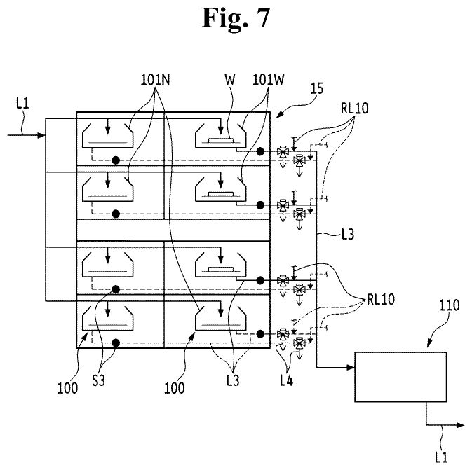

Additionally, the replenishing liquid line R10, through which the replenishing liquid passes, is illustrated as directly supplying liquid to the first tank 111 of the tank unit 110, but may preferably be connected to the recovery line L3 for replenishment. This will be described later with reference to FIG. 7.

A supply line L1 may be provided between the first tank 111 and the substrate treating assembly 101 for the passage of the treatment liquid. The treatment liquid may pass through the first and second tanks 111 and 112 before being supplied to the substrate supporting unit 101C of the substrate treating assembly 101.

The second tank 112 of the tank unit 110 may be provided on the supply line L1. The second tank 112 may be positioned downstream of the first tank 111 and upstream of the substrate treating assembly 101 to receive the second fluid discharged from the first tank 111 via the supply line L1. The treatment liquid (e.g., the second fluid) discharged from the second tank 112 may be supplied to the substrate treating assembly 101.

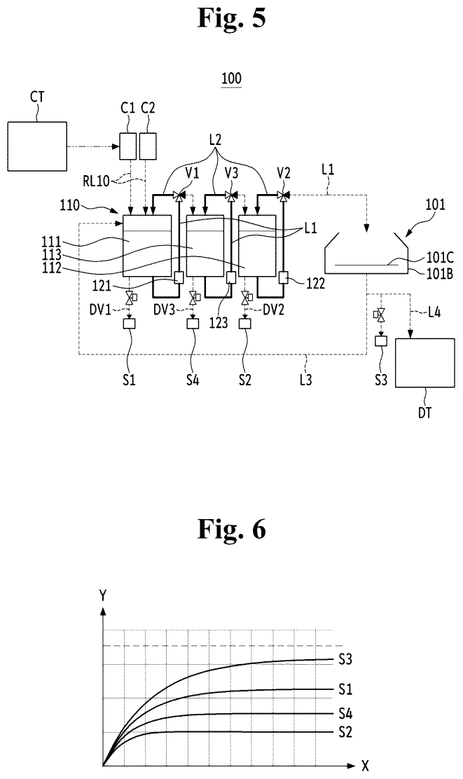

The first and second tanks 111 and 112 may have a circulation structure to prevent the sedimentation of the treatment liquid. This mechanism is the same as or similar to that in a second embodiment of the present disclosure, and thus will be described later with reference to FIG. 5.

As the treatment liquid passes through and/or is supplied, the Ti concentration may be detected, and the drainage and replenishment of the treatment liquid may be controlled based on the detected Ti concentration. For this purpose, a plurality of concentration meters (e.g., the first, second, and third concentration meters S1, S2, and S3) may be provided, and concentration values detected by the plurality of concentration meters may be transmitted to the control unit CT.

The first concentration meter S1 may measure the concentration of the second fluid passing through the first tank 111. For example, if the concentration value measured by the first concentration meter S1 exceeds a first value, meaning that the Ti concentration has reached a level that reduces etching efficiency (e.g., 25 ppm or higher), a flushing operation may be needed to discard all the reused treatment liquid and replace it with a new treatment liquid.

For the flushing operation, a first discharge line DV1 may be provided in the first tank 111, and the first concentration meter S1 may be installed in the first discharge line DV1. Since the first concentration meter S1 is for measuring the concentration of the treatment liquid passing through the first tank 111, the first concentration meter S1 may be installed in the supply line L1, which is connected to the first tank 111, and/or at the outlet of the first tank 111 (see FIG. 8).

The second concentration meter S2 may measure the concentration of the treatment liquid at a different location from the first concentration meter S1. That is, the second concentration meter S2 may measure a variation in the Ti concentration during the passage of the treatment liquid.

For example, the second concentration meter S2 may measure the treatment liquid (e.g., the second fluid) from the outlet of the second tank 112 to measure the concentration of the second fluid passing through the second tank 112. For a flushing operation in the second tank 112, a second discharge line DV2 may be provided, and the second concentration meter S2 may be installed in the second discharge line DV2. Alternatively, like and/or similar to the first concentration meter S1, the second concentration meter S2 may be installed in the supply line L1 (see FIG. 8).

The third fluid, which contains foreign substances and results from the second fluid used in the substrate treating assembly 101 to treat the substrate W, may pass through the recovery line L3. The recovery line L3 may connect the substrate treating assembly 101 and the first tank 111, thereby recovering the third fluid discharged from the substrate treating assembly 101 into the first tank 111.

The drain line L4 may branch from the recovery line L3 and may be connected to a drain tank DT. The third fluid may be discharged into the drain tank DT via the drain line L4.

For example, the Ti concentration in the third fluid discharged from the substrate treating assembly 101 may be higher during an initial process time (e.g., within 40% of the total process time for a single substrate, such as 0 to 4 seconds out of a 10-second-long process) than after the initial process time.

In other words, the Ti content in the third fluid discharged during the initial process time may be higher than that in the third fluid discharged after the initial process time. Consequently, even within the same substrate processing cycle, concentration values may be higher during the initial process time.

Accordingly, if only the third fluid discharged after the initial process time is recovered into the first tank 111, the concentration of the treatment liquid may be lower compared to when the third fluid discharged during the initial process time is recovered into the first tank 111, increasing the usable duration of the treatment liquid and reducing the need for treatment liquid replacement and/or flushing.

Therefore, in the first embodiment, the control unit CT may control the flow of the treatment liquid based on the concentration value detected by the third concentration meter S3 to ensure the recovery of the third fluid into the first tank 111 for reuse of the treatment liquid while preventing the Ti concentration from rapidly reaching a first preset value, even if the same volume of the third fluid is recovered. That is, the control unit CT may control the flow of the treatment liquid such that a third fluid with a high Ti concentration may be discharged into the rain tank DT not to be reused, and a third fluid with a low Ti concentration may be recovered into the first tank 111.

In other words, to control the flow of the treatment liquid, the third concentration meter S3 may be provided to detect the concentration of the third fluid. The third concentration meter S3 may be installed in the recovery line L3, the drain line L4, and/or a line branching from the drain line L4.

The discharge of the third fluid into the drain tank DT or the recovery of the third fluid into the first tank 111 may be determined based on the initial process time obtained through experimental data from repeated process cycles. However, to eliminate the need to derive such experimental data for different substrate types and/or treatment liquids, the third concentration meter S3 may preferably be provided, but the present disclosure is not limited thereto.

The control unit CT may receive concentration values measured by the first concentration meter S1, the second concentration meter S2, and the third concentration meter S3 and perform feedback control, thereby regulating the flow and circulation of the treatment liquid (e.g., the first, second, and third fluids) based on the concentration of the treatment liquid.

That is, based on the detected values from the first, second, and third concentration meters S1, S2, and S3, the control unit CT may adjust the flow rate of the first fluid supplied to the first tank 111, the flow rate of the third fluid discharged through the drain line L4, and the flow rate of the third fluid recovered into the first tank 111.

For example, if the concentration value detected by the third concentration meter S3 is equal to or greater than a second preset value, the drain line L4 may be opened to discharge the third fluid into the drain tank DT. If the detected concentration value is below the second preset value, the drain line L4 may be closed, and the third fluid may be recovered into the first tank 111.

When the treatment liquid is supplied to the substrate treating assembly 101, it may be supplied for a sufficient process time to ensure that the etching reaction on the substrate W may be adequately performed (e.g., continuing to supply the treatment liquid even after the etching reaction has been completed). The reaction rate may be high during the initial process time, but may then gradually or abruptly decrease, resulting in a variation in the Ti content depending on the process time for a single substrate W.

Therefore, in the first embodiment, to prevent the reuse of the third fluid discharged during the initial process time, which has a high Ti content, and to reuse only the third fluid discharged after the initial process time, which has a lower Ti content, the third fluid may be either discharged into the drain tank DT or recovered into the first tank 111 based on the concentration value detected by the third concentration meter S3.

Here, the second preset value may correspond to a value within the process time for a single substrate W, during which the reaction rate is high in the initial process time, leading to a determination that the Ti content/ratio is high for the same flow rate. That is, the second preset value may correspond to a relatively high Ti concentration, which, when the treatment liquid is reused, results in a reduction in the etching efficiency of the treatment liquid

For example, the second preset value may correspond to a Ti concentration of 5 ppm. Alternatively, it may be defined as a concentration level at which the foreign substance/Ti concentration is relatively low (e.g., assuming that the initial concentration value detected during the initial process time is 100%, and that after a certain period, the Ti content decreases to 75% or lower compared to the initial concentration value).

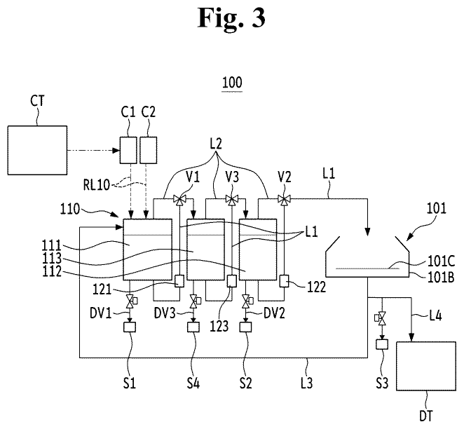

A substrate treating apparatus according to another embodiment of the present disclosure will hereinafter be described with reference to FIGS. 3 through 12, with redundant descriptions of identical features omitted.

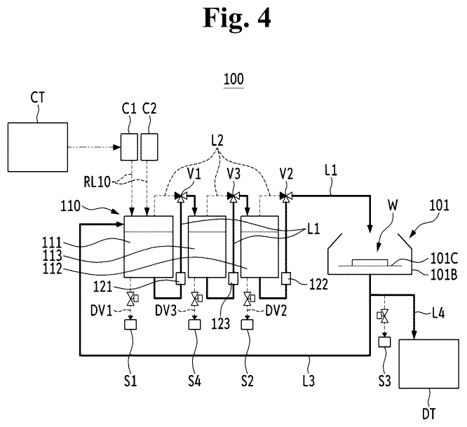

FIG. 3 is a diagram illustrating a substrate treating apparatus according to a second embodiment of the present disclosure, FIG. 4 is a diagram explaining the treatment liquid supply flow of the substrate treating apparatus according to the second embodiment of the present disclosure, and FIG. 5 is a diagram explaining the treatment liquid circulation of the substrate treating apparatus according to the second embodiment of the present disclosure. Additionally, FIG. 6 is a diagram for explaining the foreign substance concentration in the substrate treating apparatus according to the second embodiment of the present disclosure. The following description will focus mainly on the differences from the embodiment of FIG. 2 with reference to FIGS. 3 through 6.

Referring to FIGS. 3 through 6, a substrate treating apparatus 10 according to the second embodiment may include a tank unit 110, a first concentration meter S1, a second concentration meter S2, a third concentration meter S3, a recovery line L3, a drain line L4, and a control unit CT, similar to its counterpart of the first embodiment.

Additionally, the tank unit 110 may further include a third tank 113, as well as first and second tanks 111 and 112, and a fourth concentration meter S4 for detecting the concentration of the treatment liquid passing through the third tank 113.

The third tank 113 may be provided in the supply line L1 between the first and second tanks 111 and 112. That is, in the tank unit 110, the first, third, and second tanks 111, 113, and 112 may be sequentially arranged in a downstream direction such that the first tank 111 may supply the treatment liquid to the third tank 113, and the third tank 113 may supply the treatment liquid to the second tank 112.

The tank unit 110 may provide a storage space that allows the treatment liquid to be held before being supplied to a substrate treating assembly 101.

The third tank 113 may be provided between the first tank 111, which receives the replenishing liquid, and the second tank 112, which supplies the treatment liquid to the substrate treating assembly 101. The third tank 113 may ensure that sufficient heat may be applied to the treatment liquid according to the temperature required by the substrate treating assembly 101.

For example, while the temperature of the treatment liquid used for processing a substrate W (see FIG. 4) may be at least 60° C., the newly supplied treatment liquid may be at room temperature. Due to this temperature difference, if the treatment liquid is directly transferred from the first tank 111 to the second tank 112, it may not correspond to the appropriate temperature for treating the substrate W, making it difficult to properly treat the substrate W. To prevent this, the third tank 113, which serves as a buffer tank, may be provided upstream of the second tank 112.

The third tank 113, like or similar to the first tank 111 and/or the second tank 112, may include a fourth concentration meter S4 for measuring the concentration of the second fluid. The fourth concentration meter S4 may measure the concentration of the second fluid at the outlet of the third tank 113.

For example, the fourth concentration meter S4 may be provided on a third discharge line DV3 for flushing the third tank 113, but the present disclosure is not limited thereto. The fourth concentration meter S4 may also be provided in the supply line L1 at the outlet of the third tank 113 (see FIG. 8).

Referring to FIG. 4 (where solid lines indicate the supply, recovery, and drainage of the treatment liquid), the treatment liquid may be supplied from the first tank 111, in which replenishing liquids C1 and C2 are stored, to the substrate treating assembly 101 via a supply line L1, passing sequentially through the third tank 113 and the second tank 112.

At this time, to prevent an excessive increase in Ti concentration due to the treatment liquid discharged during an initial process time, the treatment liquid discharged from the substrate treating assembly 101 may be separately treated or discarded by being discharged into a drain tank DT. To allow for reuse of the treatment liquid during a process time in which the etching amount decreases during the treatment of a single substrate W (e.g., after the initial process time, such as after the first 30% of the process time for the single substrate W), if the concentration of the third fluid is at or below a second preset value, the third fluid may be recovered into the first tank 111 via the recovery line L3, instead of being discharged into the drain tank DT, such that the treatment liquid may be reused.

Here, if the treatment liquid does not flow during the process time when it is not being supplied or during its supply and/or circulation, sedimentation may occur. Therefore, the treatment liquid inside the first tank 111, the second tank 112, and/or the third tank 113 needs to be circulated.

Referring to FIG. 5 (where solid lines indicate the circulation path of the treatment liquid), the first tank 111, the second tank 112, and the third tank 113 may have a circulation structure to prevent the sedimentation of the treatment liquid. For this purpose, a plurality of branch lines L2 may be provided along the supply line L1. The branch lines L2 may branch from the supply line L1 at positions downstream of the first tank 111, the second tank 112, and the third tank 113 and may be reconnected to the first tank 111, the second tank 112, and the third tank 113. As a result, the treatment liquid discharged from the first tank 111, the second tank 112, and the third tank 113 may be recirculated through the branch lines L2 back into the first tank 111, the second tank 112, and the third tank 113, thereby ensuring continuous circulation of the treatment liquid.

At the branch point of the branch lines L2, three-way valves V1, V2, and V3 may be provided, but the present disclosure is not limited thereto. The circulation and supply of the treatment liquid may be performed separately. Alternatively, the circulation of the treatment liquid may be performed when the supply of the treatment liquid is not being performed. Thus, separate valves may be installed on each of the supply line L1 and branch lines L2, instead of providing the three-way valves V1, V2, and V3, among other possible variations.

In other words, the three-way valves V1, V2, and V3 are illustrated as having different opening conditions for the circulation of the treatment liquid and the supply of the treatment liquid, but the present disclosure is not limited thereto. Since the three-way valves V1, V2, and V3 are used to control the flow of the treatment liquid, their connection structure, arrangement, and quantity may vary, and are not particularly limited.

The second embodiment may provide a feedback control mechanism that regulates the flow of the treatment liquid based on the detected Ti concentration.

At least one of the first, second, third, or fourth concentration meters S1, S2, S3, or S4 may detect variations in the concentration of foreign substances (e.g., Ti) contained in the second or third fluid. The control unit CT may receive concentration values in real time from the first, second, third, and fourth concentration meters S1, S2, S3, and S4 and perform feedback control accordingly.

For example, if the concentration of the second or third fluid exceeds a first preset value, the first, second, and third tanks 111, 112, and 113 may be subjected to a flushing process by opening the first, second, and third discharge lines DV1, DV2, and DV3, while closing the supply line L1 and the branch lines L2 to block the circulation and supply flow of the treatment liquid in the first, second, and third tanks 111, 112, and 113.

Alternatively, the first, second, and third discharge lines DV1, DV2, and DV3 may be opened, and a separate cleaning liquid may be introduced to perform a cleaning process on multiple tanks and lines. For this purpose, the supply line L1 and the branch lines L2 may also be opened simultaneously, among other possible variations.

As mentioned earlier, a portion of the third fluid may be reused, while another portion may not be reused, depending on the Ti concentration. For example, if the concentration of the third fluid is equal to or greater than the second preset value, the third fluid may be discharged into the drain tank DT by opening the drain line L4, and accordingly, the first fluid may be supplied to the first tank 111. Conversely, if the concentration of the third fluid is equal to or less than the second preset value, the third fluid may be recovered into the first tank 111 for reuse.

Here, the first preset value (e.g., a Ti concentration of 25 ppm) may represent a concentration level at which the treatment liquid discharged from multiple tanks is difficult to reuse, serving as a criterion for determining whether a flushing process is necessary. The second preset value (e.g., a Ti concentration of 5 ppm) may represent a concentration level used to prevent the overall treatment liquid concentration in the first tank 111 from increasing excessively relative to the flow rate of the third fluid recovered into the first tank 111, serving as a criterion for determining whether the third fluid should be drained.

Referring to FIG. 6 (where the X-axis represents time and the Y-axis represents concentration), the concentration of the treatment liquid stored in the tank unit 110 may be controlled through the discharge of the treatment liquid, as previously described. Consequently, the concentration of the treatment liquid may be maintained below the first preset value (see the dashed line in FIG. 6).

Here, the treatment liquid initially stored in the second and third tanks 112 and 113 may be unused treatment liquid, starting with a foreign substance concentration of 0%. In some embodiments, substrate treatment may be carried out with no treatment liquid initially present in the first tank 111 or with a portion of the replenishing liquid supplied to the first tank 111 before substrate treatment, among other possible variations.

Additionally, in some embodiments, the control unit CT of the tank unit 110 may perform feedback control based on the concentration values measured by the first, second, and third concentration meters S1, S2, and S3 to control the flow rate of the treatment liquid. As a result, the foreign substance concentration may be maintained to become less from the first concentration meter S1 to the fourth concentration meter S4 to the second concentration meter S3.

Reference numerals 121, 122, and 123, which have not been explained earlier, may correspond to heat exchangers such as heaters that apply heat to the treatment liquid to adjust its temperature to a level suitable for substrate treatment. The heat exchangers 121, 122, and 123 may be provided in the supply line L1 for temperature control of the treatment liquid.

Furthermore, to avoid the need for additional heat exchangers 121, 122, and 123 in the branch lines L2, the heat exchangers 121, 122, and 123 may be installed upstream of the branch lines L2. That is, after being heated by the heat exchangers 121, 122, and 123 located upstream of the branch lines L2, the treatment liquid may circulate through the branch lines L2 from the first tank 111 to the second tank 112 to the third tank 113, or be supplied to the substrate treating assembly 101 via the supply line L1. Through this, the heat exchangers 121, 122, and 123 may be shared among multiple tanks, i.e., the first, second, and third tanks 111, 112, and 113, facilitating the circulation and supply of the treatment liquid.

A substrate treating apparatus according to another embodiment of the present disclosure will hereinafter be described with reference to FIGS. 7 and 8.

FIG. 7 is a diagram illustrating process chambers in which substrate treating apparatuses according to a third embodiment of the present disclosure are provided, and FIG. 8 is a diagram illustrating the initial state of a tank unit for the substrate treating apparatuses according to the third embodiment of the present disclosure.

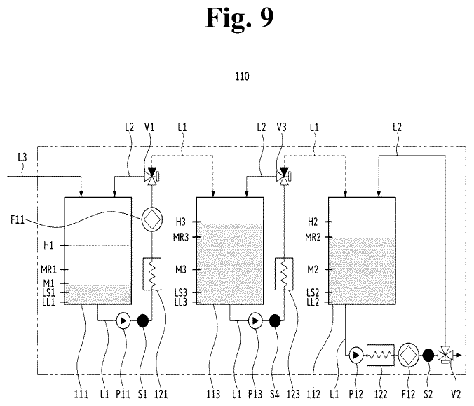

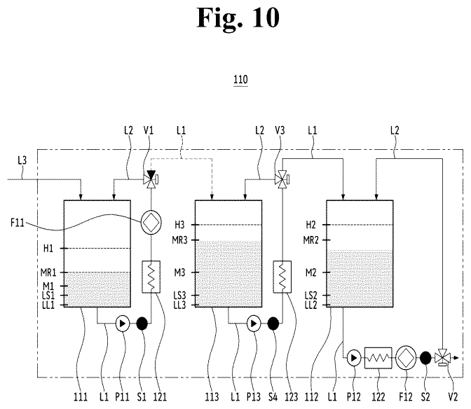

FIG. 9 is a diagram illustrating a state in which a second tank for the substrate treating apparatuses according to the third embodiment of the present disclosure is at or above a fourth level, and FIG. 10 is a diagram illustrating a state in which the second tank for the substrate treating apparatuses according to the third embodiment of the present disclosure is at or below the fourth level.

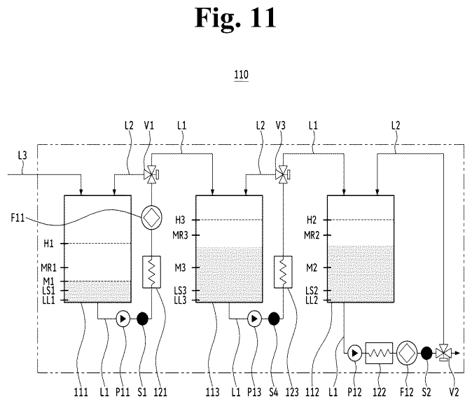

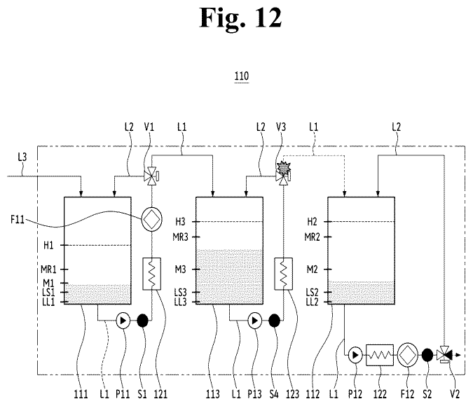

FIG. 11 is a diagram illustrating a state in which a third tank for the substrate treating apparatuses according to the third embodiment of the present disclosure is at or below the fourth level, and FIG. 12 is a diagram illustrating an abnormal condition in the treatment liquid supplied to the third tank for the substrate treating apparatuses according to the third embodiment of the present disclosure.

Referring to FIGS. 7 through 12, substrate treating apparatuses 100 according to some embodiments may differ in terms of the connection of replenishing liquid lines R10 and/or the presence of a liquid level detection unit. However, as previously mentioned, embodiments of the present disclosure may be combined with each other to create other embodiments.

In some embodiments, N substrate treating assemblies 101 (where N is a natural number, e.g., 8) may be provided. It is to be noted that since the N substrate treating assemblies 101 may operate at different processing speeds, some substrate treating assemblies 101W may be currently treating substrates W, while some substrate treating assemblies 101N may be in a state where substrates W have already been unloaded. It is also to be noted that since the substrate treating assemblies 101W treating multiple substrates W may have different process times, their treatment completion times for the substrates W may also differ.

Furthermore, for spatial efficiency and/or control efficiency, the N substrate treating assemblies 101 may be supplied with a treatment liquid from a single tank unit 110. That is, a single tank unit 110 may serve as a common source of the treatment liquid for the N substrate treating assemblies 101.

Recovery lines L3 may extend from the N substrate treating assemblies 101, merge, and then be connected to a first tank 111 of the tank unit 110.

The replenishing liquid lines R10 may be conduits for a replenishing liquid. The replenishing liquid lines R10 may be connected to the recovery lines L3. Specifically, to be provided individually, rather than in common, for the respective substrate treating assemblies 101, the replenishing liquid lines R10 may be connected upstream rather than downstream of the merging point of the recovery lines L3.

This is because if a treatment liquid containing foreign substances from the processing of substrates W is simultaneously supplied from all the N substrate treating assemblies 101 to the first tank 111, the concentration within the first tank 111 may momentarily spike due to delays and/or time differences in the supply of the replenishing liquid into the first tank 111, making it difficult to consistently maintain and manage the concentration of the treatment liquid due to potential peak points.

Conversely, in some embodiments, the replenishing liquid lines R10 may respectively correspond to the N recovery lines L3 connected to the N substrate treating assemblies 101. Since the replenishing liquid lines R10 can handle the respective substrate treating assemblies 101, peak points may not occur or may be significantly reduced, thereby facilitating concentration management. Consequently, the frequency of use may be increased in some embodiments.

Additionally, even if the processing times of the N substrate treating assemblies 101 vary and the amounts of treatment liquid used and recovered differ between the N substrate treating assemblies 101, controlling the flow rate of the replenishing liquid using the replenishing liquid lines R10, which are connected to the respective substrate treating assemblies 101, may allow for easier concentration management and precise control of the treatment liquid volume compared to supplying the replenishing liquid to the first tank 111 all at once.

That is, if the treatment liquid discharged from the N substrate treating assemblies 101 is recovered into the first tank 111 at once, the concentration may spike, making concentration management difficult. However, in some embodiments, even if all the N substrate treating assemblies 101 discharge the treatment liquid simultaneously into the first tank 111, the replenishing liquid may be supplied upstream of the merging point of the recovery lines L3. Consequently, the treatment liquid and replenishing liquid may be adjusted individually for each of the N substrate treating assemblies 101 before being supplied to the first tank 111, allowing for fine and precise management of treatment liquid concentration and volume.

In some embodiments, branch lines L2 may branch from a supply line L1 at downstream points of a plurality of first, second, and third tanks 111, 112, and 113 to be connected to the first, second, and third tanks 111, 112, and 113. The supply line L1 may be provided with heat exchangers 121, 122, and 123, one or more pumps P11, P12, and P13, and filters F11 and F12. The pumps P11, P12, and P13, like/similar to the heat exchangers 121, 122, and 123, may be provided upstream of the branch point of the branch lines L2, rather than within the branch lines L2.

Here, the pumps P11, P12, and P13 may be implemented as bellows-type pumps commonly provided in a typical substrate treating apparatus, but the present disclosure is not limited thereto.

The liquid level detection unit may detect the liquid level in the tank unit 110 and may be provided as a plurality of liquid level sensors. The liquid level detection unit may detect first, second, third, fourth, and fifth levels that are sequentially higher in an upward direction from the bottom of the tank unit 110.

Here, the first level may be positioned adjacent to the bottom of the tank unit 110. The second level may correspond to the volume of treatment liquid that can be pumped by the pumps P11, P12, and P13. The third level may correspond to the volume of treatment liquid required for processing the N substrates W. The fourth level may be higher than the level of the volume of treatment liquid required for processing the N substrates W. The fifth level, which represents the maximum liquid storage level of the tank unit 110, may be at a buffer level.

The liquid level detection unit, which detects the first, second, third, fourth, and fifth levels, may be provided as the array of liquid level sensors arranged within the tank unit 110, including first level sensors LL1, LL2, and LL3, second level sensors LS1, LS2, and LS3, third level sensors M1, M2, and M3, fourth level sensors MR1, MR2, and MR3, and fifth level sensors H1, H2, and H3.

The first level sensors LL1, LL2, and LL3 may be positioned at the first level of the tank unit 110 and may detect the treatment liquid at the first level. The first level sensors LL1, LL2, and LL3 may be provided to detect whether drainage is necessary. For example, the first level sensors LL1, LL2, and LL3 may detect whether the liquid level falls below the first level to determine whether all the treatment liquid has been discharged for a flushing operation.

The second level sensors LS1, LS2, and LS3 may be positioned at the second level of the tank unit 110 and may detect the treatment liquid at the second level. The second level sensors LS1, LS2, and LS3 may be provided as sensors for controlling whether to drive the pumps P11, P12, and P13 via a control unit CT. That is, the second level sensors LS1, LS2, and LS3 may be provided for the control unit CT to control the pumping operations of the pumps P11, P12, and P13.

The third level sensors M1, M2, and M3 may be positioned at the third level of the tank unit 110 and may detect the treatment liquid at the third level. Since the third level corresponds to the volume of the treatment liquid required for processing N substrates W, the third level sensors M1, M2, and M3 may ensure that the treatment liquid does not run short when the N substrate treating assemblies 101 are supplied simultaneously.

For example, if the treatment liquid stored in the second tank 112 falls below the third level, the supply of the treatment liquid may be interrupted when any one of the N substrate treating assemblies 101 is treating a substrate W, potentially leading to substrate defects and yield reduction. To prevent this, the third level sensors M1, M2, and M3 are provided.

The fourth level sensors MR1, MR2, and MR3 may be positioned at the fourth level of the tank unit 110 and may detect the treatment liquid at the fourth level. The fourth level sensors MR1, MR2, and MR3 may be provided to ensure timely replenishment of the second and third tanks 112 and 113. Specifically, the fourth level sensors MR1, MR2, and MR3 may detect the treatment liquid at a level higher than the third level, thereby allowing for frequent replenishment of the treatment liquid.

The fifth level sensors H1, H2, and H3 may be positioned at the fifth level of the tank unit 110 and may detect the treatment liquid at the fifth level. The fifth level sensors H1, H2, and H3 may be provided to allow the control unit CT to determine whether the treatment liquid has reached the buffer level.

In some embodiments, the control unit CT may adjust the flow rate of the treatment liquid discharged from the tank unit 110 based on liquid levels detected by the liquid level detection unit.

The control unit CT may control the flow rate of the replenishing liquid supplied through the replenishing liquid lines R10 to the recovery lines L3 connected to the substrate treating assemblies 101W that are currently treating substrates W, among the N substrate treating assemblies 101. That is, the control unit CT may use valves to regulate the flow rate of the replenishing liquid, ensuring that the treatment liquid is supplied to the substrate treating assemblies 101W currently processing substrates W while not being supplied to the substrate treating assemblies 101N that are idle.

In some embodiments, the control unit CT may control the drainage and/or recovery of the treatment liquid based on the concentration values detected by a concentration measurement unit. Since this has been described earlier, a detailed explanation is omitted here.

Furthermore, in some embodiments, the control unit CT may regulate the supply of the treatment liquid to the tank unit 110 through valve control based on liquid levels detected by the liquid level detection unit.

It will hereinafter be described how the control unit CT regulates the supply of the treatment liquid based on a liquid level.

Referring to FIG. 8, when a flushing operation is completed, the tank unit 110 may be fully replenished with an unused new treatment liquid. In some embodiments, the second and third tanks 112 and 113 are in a state of being fully replenished with new treatment liquid, whereas the first tank 111 may be in an emptied state. Here, the first tank 111 may be initially empty, but may have the treatment liquid recovered or the replenishing liquid supplied during the treatment of multiple substrates W.

Since the treatment liquid stored in the second and third tanks 112 and 113 is at or above the second level, the control unit CT may control the opening and closing of three-way valves V2 and V3 to circulate the treatment liquid in the second and third tanks 112 and 113.

Referring to FIG. 9, during the process of treating the substrate W, the liquid level of the second tank 112 may gradually decrease as the treatment liquid is supplied to the substrate treating assembly 101. As mentioned in some embodiments, to ensure that the treatment liquid with a high foreign substance (e.g., Ti) concentration is drained, if the concentration value detected by the third concentration meter S3 is equal to or greater than the second preset value, the drain lines L4 may be opened to discharge the treatment liquid into the drain tank DT. If the concentration value is below the second preset value, the drain lines L4 may be closed, and the treatment liquid may be recovered into the first tank 111.

At this time, the treatment liquid stored in the second tank 112 and the third tank 113 may continue to circulate, while its temperature may be maintained by heat exchangers 121, 122, and 123.

Additionally, if the treatment liquid level in the first tank 111 is at or above the second level, the control unit CT may control the opening and closing of a three-way valve V1 to allow circulation of the treatment liquid in the first tank 111.

The control unit CT may prevent the treatment liquid from being pumped from any of the first, second, and third tanks 111, 112, and 113 if their liquid level, as detected by the liquid level detection unit, is at or below the second level. This is because if the pumps P11, P12, and P13 in the substrate treating apparatus are bellows-type pumps, they may continue to pump air, which may cause tear due to air pressure or result in leakage of the treatment liquid. Thus, the control unit CT may allow a pumping operation to be performed when minimal air is present.

Referring to FIGS. 10 and 11, if the liquid level in the second tank 112 falls to or below the fourth level, the control unit CT may control the three-way valve V3 of the third tank 113 to direct the treatment liquid from the third tank 113 to the second tank 112.

Additionally, referring to FIG. 11, if the liquid level in the third tank 113 falls to or below the fourth level, the control unit CT may control the three-way valve V1 of the first tank 111 to direct the treatment liquid from the first tank 111 to the third tank 113.

At this time, if the treatment liquid stored in the tank unit 110 is at or above the second level, the control unit CT may control the opening and closing of three-way valves V1, V2, and V3 to ensure circulation of the treatment liquid.

Meanwhile, referring to FIG. 12, if the liquid level detection unit detects the liquid level in the second tank 112 at or below the third level, the control unit CT may stop the supply of the treatment liquid to the substrate treating assemblies 101 and halt the operation of the substrate treating assemblies 101.

For example, if a malfunction or leakage occurs in the three-way valve V3, provided downstream of the third tank 113, then even when the liquid level in the second tank 112 falls to or below the fourth level, and the control unit CT controls the three-way valve V3 of the third tank 113 to supply the treatment liquid to the second tank 112, the treatment liquid may not be supplied to the second tank 112 and may instead be supplied to the substrate treating assemblies 101. As a result, the liquid level in the second tank 112 may continue to decrease and eventually fall to or below the third level.

If the supply of the treatment liquid is interrupted during the treatment of substrates W, the substrates W may be improperly treated, leading to defects. To prevent depletion of the treatment liquid during processing and ensure that a shortage in one of the N substrate treating assemblies 101 does not interrupt the supply of the treatment liquid, the control unit CT may stop the supply of the treatment liquid to the substrate treating assemblies 101 and halt the operation of the substrate treating assemblies 101 once the liquid level in the second tank 112 falls to or below the third level, but only after the ongoing treatment of the substrates W is completed.

However, the third tank 113 may supply the treatment liquid to substrates W not directly, but indirectly via the second tank 112. Thus, as long as the second tank 112 does not experience a shortage of the treatment liquid, i.e., as long as the liquid volume in the second tank 112 remains at or above the third level, the substrate treatment operation of the substrate treating assemblies 101 may continue even if the liquid volume in the third tank 113 falls to or below the third level.

Although the embodiments of the present invention have been described above with reference to the accompanying drawings, it will be understood by those skilled in the art that various modifications and changes can be made without departing from the spirit or essential characteristics of the present invention. Therefore, the above-described embodiments should be considered in all respects as illustrative and not restrictive.

What is claimed is:

1. A substrate treating apparatus comprising:
a substrate treating assembly including a substrate supporting unit configured to support a substrate treated with a treatment liquid and a bowl unit surrounding the substrate supporting unit;
a tank unit including a plurality of tanks, the plurality of tanks including first and second tanks that are configured to receive the treatment liquid supplied to the substrate treating assembly and are arranged in series in a downstream direction, wherein the second tank is configured to supply the treatment liquid to the substrate;
a liquid level detection unit configured to detect a liquid level of the tank unit; and
a control unit configured to regulate a flow rate of the treatment liquid discharged from the tank unit based on the liquid level detected by the liquid level detection unit.

2. The substrate treating apparatus of claim 1, wherein:
the liquid level detection unit is configured to detect a first level, a second level, a third level, a fourth level, and a fifth level that are sequentially higher in an upward direction from a bottom surface of the tank unit,
N substrate treating assemblies are provided, wherein N is a natural number,
the tank unit is configured to supply the treatment liquid in common to the N substrate treating assemblies, and
the liquid level detection unit includes: a first level sensor configured to detect the treatment liquid at the first level; a second level sensor configured to detect the treatment liquid at the second level; a third level sensor configured to detect the treatment liquid at the third level; a fourth level sensor configured to detect the treatment liquid at the fourth level; and a fifth level sensor configured to detect the treatment liquid at the fifth level, wherein the fourth level is higher than a level corresponding to a volume of the treatment liquid required to treat N substrates, and
the control unit is further configured to control the treatment liquid to be supplied to a tank where the liquid level detection unit detects the treatment liquid at or below the fourth level.

3. The substrate treating apparatus of claim 2, wherein:
the tank unit further includes a third tank,
the first, third, and second tanks are sequentially arranged in series in a supply line through which the treatment liquid flows, and
the first and third tanks are further configured to supply the treatment liquid to their downstream tanks.

4. The substrate treating apparatus of claim 3, wherein:
the third level corresponds to the volume of the treatment liquid required to treat the N substrates, and
the control unit is further configured to stop supplying the treatment liquid to the substrate treating assemblies and halt operations of the substrate treating assemblies during the treatment of the substrates, when the liquid level detection unit detects the treatment liquid in the second tank at or below the third level.

5. The substrate treating apparatus of claim 4, wherein one or more branch lines are provided in the supply line such that the treatment liquid stored in the tank unit is circulated, thereby enabling circulation of the treatment liquid stored in at least one of the plurality of tanks.

6. The substrate treating apparatus of claim 5, wherein:
the one or more branch lines branch from a downstream position of the plurality of tanks in the supply line and are connected to the plurality of tanks,
the supply line is provided with one or more heat exchangers and one or more pumps,
the one or more pumps are provided upstream of a branch point of the one or more branch lines rather than within the one or more branch lines,
the second level corresponds to a position of a volume of the treatment liquid that can be pumped by the one or more pumps, and
the control unit is further configured to prevent pumping of the treatment liquid from a tank where the liquid level detection unit detects the treatment liquid at or below the second level.

7. The substrate treating apparatus of claim 6, wherein:
the one or more heat exchangers are provided upstream of the branch point of the one or more branch lines rather than in the one or more branch lines,
the one or more branch lines branch from a downstream position of the third tank and are connected to the third tank, and
the treatment liquid passing through the third tank circulates through the one or more branch lines and is supplied to the second tank after undergoing heat exchange in the one or more heat exchangers.

8. The substrate treating apparatus of claim 1, wherein the first tank is connected to recovery lines through which at least a portion of the treatment liquid discharged from the substrate treating assembly is recovered.

9. The substrate treating apparatus of claim 8, further comprising:
replenishing liquid lines through which a replenishing liquid, which is an unused treatment liquid, flows;
wherein:
the recovery lines extend from the N substrate treating assemblies, merge, and are connected to the tank unit, and
the replenishing liquid lines are connected to the recovery lines, upstream of a merging point of the recovery lines, rather than downstream of the merging point.

10. The substrate treating apparatus of claim 9, wherein:
the replenishing liquid lines are provided in correspondence with the N substrate treating assemblies and are respectively provided for N recovery lines connected to the N substrate treating assemblies, and
the control unit is further configured to control a flow rate of the replenishing liquid supplied through the replenishing liquid lines such that the replenishing liquid is supplied to a recovery line connected to a substrate treating assembly that has treated a substrate, among the N substrate treating assemblies.

11. The substrate treating apparatus of claim 8, further comprising:
a concentration measurement unit including one or more concentration meters configured to measure a concentration of the treatment liquid passing through the tank unit to detect a concentration of foreign substances detached from the treatment of the substrate or a change in the concentration;
a first discharge line configured to discharge the treatment liquid from the first tank; and
a second discharge line configured to discharge the treatment liquid from the second tank.

12. The substrate treating apparatus of claim 11, wherein:
drain lines that branch from the recovery lines to drain a portion of the treatment liquid discharged from the substrate treating assemblies and are connected to a drain tank are provided in the recovery lines, and
the control unit is further configured to regulate the flow rate of the treatment liquid passing through the tank unit based on the concentration of the treatment liquid detected by the concentration measurement unit.

13. The substrate treating apparatus of claim 12, wherein the concentration measurement unit includes: a first concentration meter configured to measure the concentration of the treatment liquid passing through the first tank; a second concentration meter configured to measure the concentration of the treatment liquid passing through the second tank; and a third concentration meter provided in the recovery lines.

14. The substrate treating apparatus of claim 13, wherein the control unit is further configured to, when the concentration measurement unit detects that the concentration of the treatment liquid has reached or exceeded a first preset value corresponding to a concentration of the foreign substances at which reuse of the treatment liquid becomes difficult: open the first discharge line when the first concentration meter detects a concentration of the foreign substances equal to or greater than the first preset value; open the second discharge line when the second concentration meter detects a concentration of the foreign substances equal to or greater than the first preset value; and open the drain lines when the third concentration meter detects a concentration of the foreign substances equal to or greater than the first preset value.

15. The substrate treating apparatus of claim 14, wherein
the foreign substances include titanium, and
the first preset value corresponds to a titanium concentration of 25 ppm.

16. The substrate treating apparatus of claim 13, wherein the control unit is further configured to: open the recovery lines connected to both the substrate treating assemblies and the first tank, to recover the treatment liquid into the first tank, when a concentration of the foreign substances detected by the third concentration meter is equal to or less than a second preset value, which corresponds to a foreign substance content reduced to 75% or lower, or when the foreign substances include titanium and a concentration of the titanium is less than 5 ppm; and open the drain lines to discharge the treatment liquid into the drain tank when the concentration of the foreign substances detected by the third concentration meter is greater than the second preset value or is 5 ppm or higher.

17. The substrate treating apparatus of claim 1, wherein the treatment liquid includes an etchant for etching the substrate.

18. A substrate treating apparatus comprising:
a substrate treating assembly including a substrate supporting unit configured to support a substrate and a bowl unit surrounding the substrate supporting unit;
a first tank configured to receive a first fluid, store a second fluid mixed with the first fluid, and discharge the second fluid to the outside, the first tank including a first discharge line provided with a first concentration meter configured to measure a concentration of the second fluid;
a supply line connecting the substrate treating assembly and the first tank;
a second tank provided downstream of the first tank in the supply line and configured to supply the second fluid to the substrate treating assembly, and discharge the second fluid to the outside, the second tank including a second discharge line provided with a second concentration meter configured to measure a concentration of the second fluid;
a third tank provided between the first and second tanks in the supply line, the third tank including a third discharge line configured to discharge the second fluid to the outside;
branch lines branching from the supply line and respectively connected to the first, second, and third tanks;
a recovery line through which a third fluid, which is the second fluid mixed with titanium after treating the substrate in the substrate treating assembly, flows, the recovery line connecting the substrate treating assembly and the first tank;
a drain tank including a drain line that either branches from the recovery line or is connected near the recovery line to the substrate treating assembly, the drain tank being configured to store the third fluid;
a third concentration meter provided in the drain line and configured to measure a concentration of the third fluid;
a fourth concentration meter provided in the third discharge line and configured to measure a concentration of the second fluid discharged from the third tank;
a heater provided upstream of a branch point of the branch lines in the supply line; and
a control unit configured to receive concentration values measured by the first, second, and third concentration meters and to control flow rates of the first and second fluids,
wherein
at least one of the first, second, or third concentration meters is configured to detect a concentration of titanium contained in the second or third fluid, or a change in the concentration, and
the control unit is further configured to: open the first, second, and third discharge lines when at least one of the first, second, third, or fourth concentration meters detects that the concentration of titanium in the second or third fluid is equal to or greater than 25 ppm; open the recovery line to recover the third fluid into the first tank when the concentration of titanium detected by the third concentration meter is less than 5 ppm; and open the drain line to discharge the third fluid into the drain tank when the concentration of titanium detected by the third concentration meter is equal to or greater than 5 ppm.
